(19) United States
(12) Patent Application Publication
(10) Pub. No.: US 2026/0311737 A1
(43) Pub. Date: Oct. 8, 2026

(54) STRUCTURE AND METHOD FOR IN-MEMORY LOGIC GATES USING GAIN-CELL EMBEDDED DRAM (GC-EDRAM)

(71) Applicant: Technion Research & Development Foundation Limited, Haifa (IL)

(72) Inventors: Shahar KVATINSKY, Haifa (IL); Barak HOFFER, Haifa (IL)

(73) Assignee: Technion Research & Development Foundation Limited, Haifa (IL)

(21) Appl. No.: 19/637,006

(22) Filed: Apr. 2, 2026

Related U.S. Application Data
(60) Provisional application No. 63/782,042, filed on Apr. 2, 2025.

(51) Int. Cl. G11C 11/405; H03K 19/20

(52) U.S. Cl. CPC G11C 11/405; H03K 19/20

(57) ABSTRACT

An electronic device has gain cell (GC) embedded dynamic random access memory (eDRAM) for memory storage which can also be used for processing in memory. The GC eDRAM comprises an array of bit cells arranged in columns, each bit cell extending between a read bit line and a write bit line of a respective column, and an additional transistor for each column, connected between the respective read bit line and respective write bit line of the column, wherein the additional transistor, when enabled, provides a conducting path between the read bit line and the write bit line of the respective column. The conducting path provides a dependency between the input and the output allowing logic operations with bit cells in the array.

### RELATED APPLICATION(S)

This application claims the benefit of priority under 35 USC § 119(e) of U.S. Provisional Patent Application No. 63/782,042 filed on Apr. 2, 2025, the contents of which are all incorporated by reference as if fully set forth herein in their entirety.

### FIELD AND BACKGROUND OF THE INVENTION

The present invention, in some embodiments thereof, relates to In-Memory Logic Gates using Gain-Cell Embedded DRAM (GC-eDRAM), a method of using the same and a memory chip using in memory enabled GC-eDRAM.

As applications become more complex and data-intensive, embedded memories increasingly dominate the silicon area of system-on-chips (SoCs). Six-transistor (6T) static random-access memory (SRAM) technology is commonly favored for embedded memory in many applications. Yet, its large size and high static power consumption often account for a significant portion of the area and power budgets of SoCs.

Traditional memory of type 1T-1C embedded DRAM (eDRAM) serves as a high-density alternative to SRAM, but the additional process steps required to fabricate the cell capacitor and reliability concerns in deeply scaled process nodes have curbed its widespread use.

Embedded memories are the working memories on board the chip, holding current data that is being worked on, as opposed to long term memory which is usually off the chip. Embedded memories generally use volatile storage to give the fastest retrieval times.

GC-eDRAM, or Gain-Cell Embedded Dynamic Random-Access Memory, is a type of embedded DRAM that stores data using a gain-cell instead of the conventional 1-transistor/1-capacitor DRAM cell. A gain-cell typically uses 2-4 transistors to hold data dynamically and does not need a capacitor. Because it does not require a deep-trench or stacked capacitor, it is fully CMOS-compatible and integrates easily into logic processes.

Gain-cell (GC) eDRAM is gaining traction as an alternative to both SRAM and 1T-1C eDRAM, offering higher density and lower leakage power consumption than SRAM, while avoiding the process incompatibility of conventional eDRAM with standard CMOS processes. Gain-Cell eDRAM uses multiple transistors, including two- and three-transistor configurations, to store data. Gain-cell eDRAM offers advantages such as the above-mentioned compatibility with standard CMOS processes, making it easier to integrate with digital systems, and provides higher storage density compared to SRAM. Gain-cell eDRAM further avoids destructive read operations common in traditional eDRAM. In summary, gain-cell eDRAM has better integration capabilities and fewer manufacturing constraints.

Traditionally, enhancing on-chip memory has been the go-to strategy to boost the performance of data-centric applications, but it often falls short. Standard architectures typically entail significant overhead due to the transfer of data between the memory and processor, leading to high energy consumption and causing latency and bandwidth problems that hinder performance. To meet the growing demand for computationally intensive tasks and to overcome the constraints of conventional computing structures, processing-in-memory (PIM) integration has become a pivotal breakthrough, improving performance of SRAM and DRAM-based systems. PIM enables computational tasks to be carried out within the memory, effectively mitigating these challenges, and thus reduces the need for extensive data transfer, conserving energy and reducing stress on the memory hierarchy.

The known PIM solutions for GC-eDRAM rely on processing in additional peripheral circuits near the memory, and not the bit cells themselves. This requires additional area and has higher latency. More specifically, PIM proposals of the existing art may use GC-eDRAM but carry out computation in peripheral circuits, not inside the bit cell themselves. The memory array itself is thus not used as a computational substrate, and the design requires extra logic outside the array, increasing silicon area, latency and energy per operation. As a result there has been little innovation in the PIM field with GC-eDRAM.

Other PIM solutions for embedded memories use either SRAM bit cells that require larger area (6-10 transistors in each SRAM bit cell compared to 2-4 transistors in GC-eDRAM), or 1T-1C DRAM which suffers from reliability issues and is not compatible with standard CMOS processes.

### SUMMARY OF THE INVENTION

The present embodiments may allow GC-eDRAM be used to carry out logic operations for PIM in the bit cells themselves.

The present embodiments may provide in-memory computation with GC-eDRAM memory to enable PIM. A technique is disclosed to use GC for performing in-memory logic operations, with minor changes to the GC array structure, and with no additional peripheral circuits.

The structure of the bit cells may be modified by adding a single transistor for each column to conditionally connect the read bit line of the column to the write bit line of the same column. When the transistor is enabled, a conducting path is provided between the inputs and the output and the cell currently addressed is enabled for a logic operation.

In addition, the output of the cell is initialized with a value of 1.

Another way of achieving the enablement of logic operations using GC-eDRAM, is to change the memory array structure by alternating the write-bit-line (WBL) and read-bit-line (RBL) connection for every pair of rows. For each column, the bit cells in even rows will have their WBL (EWBL) connected to the RBL of bit cells in odd rows (ORBL), and vice versa. It is noted that the use of the terms even and odd is simply to distinguish between successive rows and is not connected with any specific row structure.

With this structure, it is possible to use the read current of the inputs as the write current for the output, which means the result stored in the output depends on the state of the inputs, and thus manifests the result of a logic operation. We can construct n-bit logic operations performed in parallel across all columns, from inputs in even rows to an output in an odd row or the other way around.

The present embodiments may thus provide stateful logic inside the GC-eDRAM array, in which bit cells participate directly in logic evaluation.

Accordingly there is no need for complex peripheral computing, and the result is lower area utilization, less data movement, and lower latency According to an aspect of some embodiments of the present invention there are provided gain cell (GC) embedded dynamic random access memory (eDRAM) devices and methods for enabling processing-in-memory (PIM) operations. Two alternative structural modifications to the GC-eDRAM array are disclosed, each enabling in-memory logic operations. In one structure, embodiments provide a GC eDRAM device with an array of bit cells arranged in columns, where each column includes an additional transistor connected between the read bit line and write bit line. This additional transistor, when enabled, creates a conducting path that allows for logic operations within a currently addressed bit cell in the column.

Embodiments of the array may initialize an output node of the currently addressed bit cell to a value of 1 for the logic operation.

In embodiments, two bit cells of the array may be configured with the additional transistor to operate as a NOT gate.

In embodiments, three bit cells of the array are configured with the additional transistor to operate as a NOR gate.

Embodiments also encompass methods of manufacturing such GC eDRAM devices, including the steps of providing a memory circuit with GC eDRAM cells arranged in columns and adding a transistor for each column to connect the read and write bit lines. This structure enables PIM operations by creating a conducting path between input and output nodes of addressed cells.

In another aspect, embodiments may provide methods for carrying out PIM logic operations in GC eDRAM arrays. These methods involve selecting a cell for a logic operation, conditionally connecting the read and write bit lines in the cell's column, initializing the output to a value of 1, and performing the logic operation on the stored data.

In the second structure for a GC eDRAM capable of logic, for each column, write-bit-lines (WBLs) of bit cells in even rows are connected to read-bit-lines (RBLs) of bit cells in odd rows, and vice versa. This arrangement enables logic operations to be performed using read currents of input bit cells as write currents for output bit cells, resulting in outputs dependent on input states. Additionally, embodiments may include methods for carrying out logic operations in such devices, using read currents of inputs as write currents for outputs. These methods allow for parallel execution of multiple logic operations across the array, with inputs in even rows and outputs in odd rows, or vice versa.

Embodiments may thus achieve efficient means for enabling in-memory computation in GC eDRAM devices, offering potential improvements in processing speed and energy efficiency for various computing applications.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified diagram of prior art GC-eDRAM cells;

FIG. 2 is a table of GC-eDRAM cells with their relevant dates of inception;

FIG. 3 is a simplified diagram showing the modification of a column of GC-eDRAM cells with a logic enabling transistor linking the write bit line to the read bit line according to embodiments of the present invention;

FIG. 4 is a simplified diagram showing a NOT gate according to embodiments of the present invention;

FIG. 5 is a simplified diagram showing a NOR gate according to embodiments of the present invention;

FIG. 6 is a simplified diagram showing a GC eDRAM cell modified for the present invention by reversing the read and write bit lines for alternating rows of the column;

FIG. 7 is a simplified flow chart illustrating a method of manufacture of GC-eDRAM according to embodiments of the present invention;

FIG. 8 is a simplified flow chart illustrating a method of using the GC-eDRAM for processing in memory (PIM) logic operations; and

FIG. 9 is a simplified flow chart illustrating a method of using the alternative WBL/RBL GC-eDRAM construction of FIG. 6.

### DESCRIPTION OF SPECIFIC EMBODIMENTS OF THE INVENTION

The present invention, in some embodiments thereof, relates to In-Memory Logic Gates using Gain-Cell Embedded DRAM (GC-eDRAM), a method of using the same and a memory chip using in memory enabled GC-eDRAM.

The present embodiments may carry out logic computations using GC-eDRAM bit cells. They use a simple concept to perform in-memory logic operations in the GC structure, enabled by a minor change to the GC-eDRAM array structure. The embodiments are fully compatible with standard semiconductor technologies.

Using the present embodiments, transitioning SoCs from SRAM and DRAM to GC-eDRAM in data-intensive applications may lead to higher memory and compute densities and lower power consumption, while gaining PIM capabilities. PIM using GC-eDRAM enhances processing efficiency by adding processing capabilities to the bit cells, facilitating parallelism and local computation, which accelerates task execution and improves overall system throughput with reduced energy consumption.

The present embodiments may enable parallel processing of data within standard semiconductor technology. Embodiments may combine the advantages of technology-mature SRAM with dense eDRAM. The present embodiments require only a minor change to the existing GC-eDRAM memory architecture.

Parallel processing and the reduced data transfer which in-memory logic provides may lead to performance and energy improvements for many applications such as AI.

In the following the NOR gate and the NOT gate are both described. All logic operations can in fact be implemented with NOR gates alone so that even the NOT gate is not strictly necessary.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

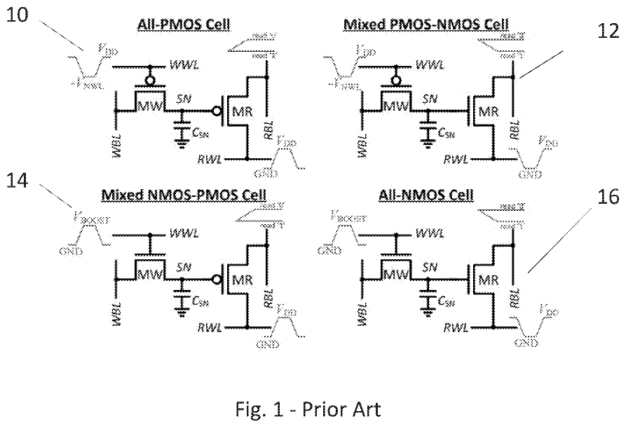

Referring now to the drawings, FIG. 1 illustrates a range of standard GC-eDRAM cells, and the compatibility with CMOS is readily apparent. Properties of the GC-eDRAM cells include being logic process compatible, particularly with CMOS, and having a non-destructive read (compared to DRAM). Four types of cell are shown, an all PMOS cell 10, a mixed PMOS NMOS cell 12, a mixed NMOS PMOS cell 14 and finally an all NMOS cell 16. The cells all have three components, two transistors MW and MR and a capacitor Csn.

GC-eDRAM is useful for SRAM replacement, and as an SRAM cell has a 6 Transistor minimum the cell density is automatically increased.

GC-eDram requires refresh cycles and has a data retention time in the range of 1 μs for the two-transistor cell to 100 μs for the four-transistor cell. The different numbers of transistors per cell, 2T, 3T, 4T, etc may be considered as different types of GC-eDRAM.

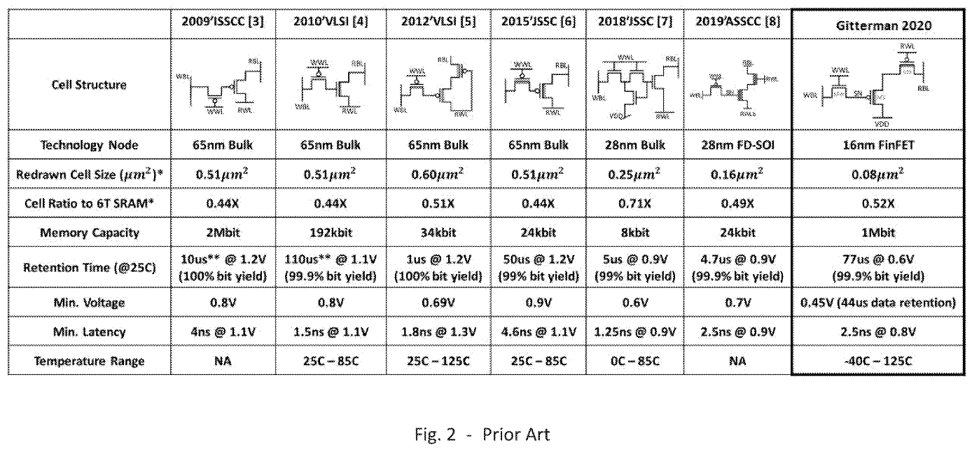

FIG. 2 illustrates seven different cell structures for different variations of GC-eDRAM together with their dates of publication, technology mode, density as a fraction of the equivalent SRAM, density in terms of memory capacity, retention time, minimum voltage, minimum latency and temperature range.

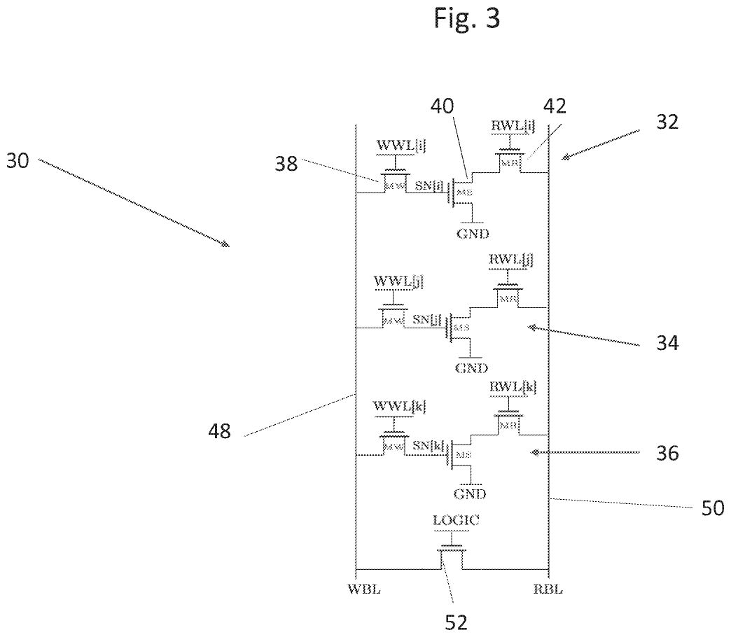

FIG. 3 is a simplified schematic diagram illustrating how the cells of FIGS. 1 and 2 may be modified for Stateful in-memory logic according to an embodiment of the present invention. One column 30 of an array consists of three, 32, 34 and 36, of the cells of Gitterman 2020 of FIG. 2. Each cell consists of a write transistor 38, MW, a storage transistor 40, MS, and a read transistor MR 42. The write transistor is connected to the write bit line 44, to the given row, (i, j, k) of write word line WWL and to the storage transistor 40 of the same row. The storage transistor 40 is located between the write transistor 38, ground and the read transistor 42. The read transistor 42 is connected to the storage transistor 40, the read word line of the given row (i, j, k) and the read bit line 50. As shown, repeated structures in a column link the write bit line 48 and the read bit line 50 in the conventional way to form the bit cells. In addition, for each column, a logic enabling transistor 52 links the two lines 48 and 50. When the logic enabling transistor conducts, the cells of the given column are enabled for logic operations, as will be explained below.

The figure shows cells of standard structure, for one column in an array.

In operation, a Write operation involves selecting WWL, and charging SN from the write bit line WBL. For a read operation RWL for the given row is selected, and the current from the read bit line RBL is sensed.

For a logic operation the added transistor 52 is set at the bottom of the respective column to connect the write bit line WBL to the read bit line RBL.

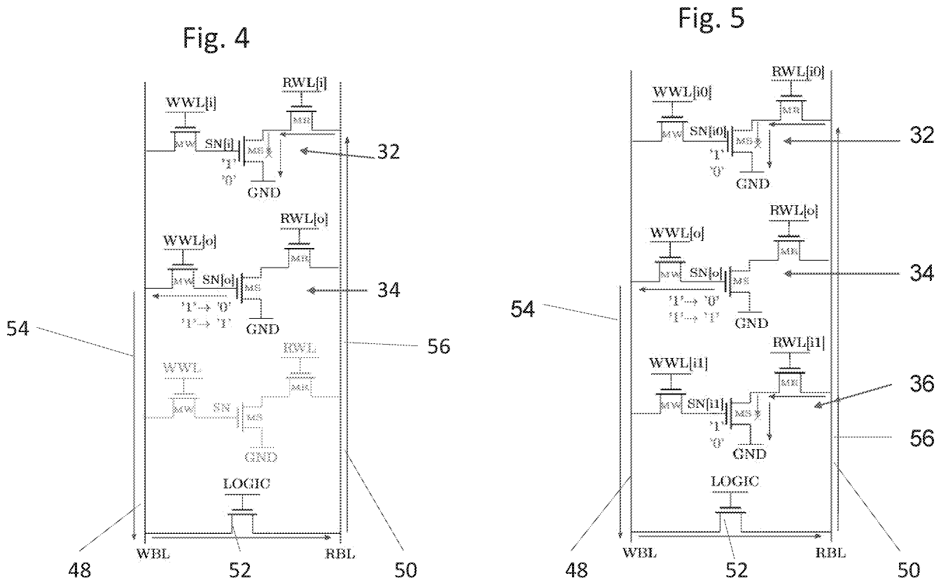

FIG. 4 is a simplified diagram showing how to construct a NOT gate from two of the bit cells 32, 34, together with setting of the logic enabling transistor 52 shared by the column, according to embodiments of the present invention. The input is indicated by arrow 54 and the output by arrow 56. The output 56 is initialized to ‘1’. Driving the LOGIC line performs the operation. If the input is ‘0’ the output will stay at ‘1’, and If the input is ‘1’, the output will switch to ‘0’. Thus the NOT gate function of table 1 is achieved.

TABLE 1
The truth table for the NOT gate

| IN | OUT |
|---|---|
| ‘0’ | ‘1’ |
| ‘1’ | ‘0’ |

FIG. 5 illustrates how three cells of GC-eDRAM, 32, 34 and 36, may be operated together with the logic enabling transistor 52 as a NOR gate. Again arrow 54 indicates the input and arrow 56 indicates the output.

Again, the output 56 is initialized to ‘1’. Driving the LOGIC line performs the operation. If both inputs are ‘0’ the output will stay at ‘1’. If at least one input is ‘1’, the output will switch to ‘0’ to give the NOR gate behavior as specified in Table 2.

TABLE 2
Truth Table for a NOR gate

| IN0 | IN1 | OUT |
|---|---|---|
| ‘0’ | ‘0’ | ‘1’ |
| ‘0’ | ‘1’ | ‘0’ |
| ‘1’ | ‘0’ | ‘0’ |
| ‘1’ | ‘1’ | ‘0’ |

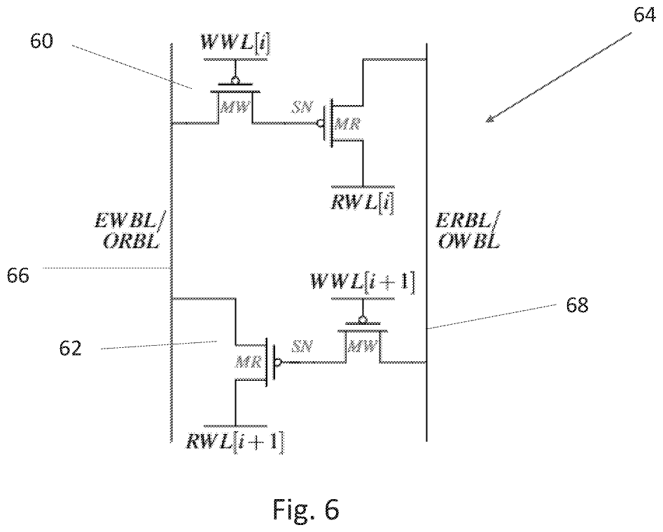

Reference is now made to FIG. 6, which shows another way of achieving the enablement of logic operations using GC-eDRAM. In FIG. 6, two successive cells 60 and 62 of a column 64 are shown and the two cells 60, 62 are respectively aligned in opposite directions, meaning their write bit line and read bit line connections are reversed with respect to one another. That is to say the embodiment involves modifying the memory array structure by alternating the write-bit-line (WBL) and read-bit-line (RBL) connection for every pair of rows. For each column, the bit cells in even rows will have their WBL (EWBL) connected to the RBL of bit cells in odd rows (ORBL), and vice versa. Thus bit line 66 forms the even write bit line EWBL and the odd read bit line ORBL. But bit line 68 forms the even read bit line and the odd write bit line.

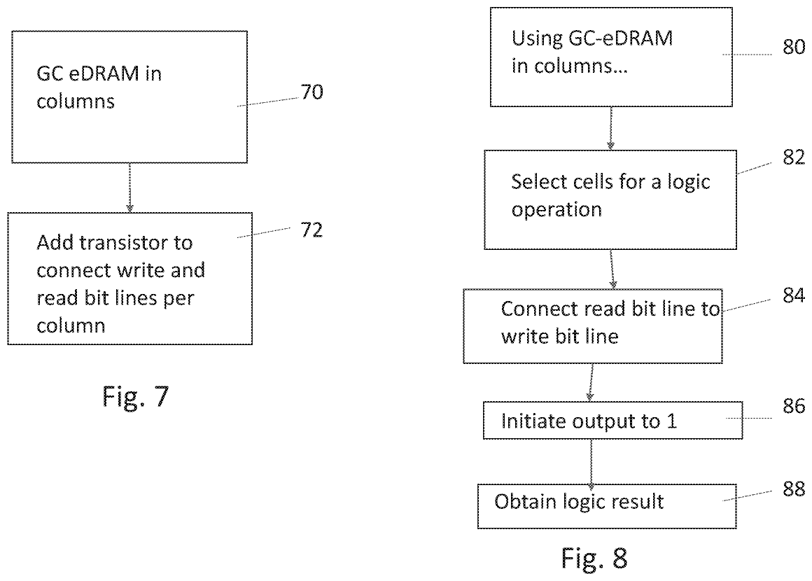

Reference is now made to FIG. 7, which is a simplified flow chart illustrating a method of manufacture according to embodiments of the present invention of a gain cell (GC) embedded dynamic random access memory (eDRAM)memory array for enabling processing-in-memory (PIM) operations in logic cells.

The method involves providing 70 embedded memory in the dedicated integrated circuit in which GC eDRAM cells are arranged in columns between respective read bit lines and write bit lines, as for example in the various examples given above. Then, in the manufacturing process, a transistor is added 72, typically one transistor for each column respectively. The added transistor connects between the read bit line and the write bit line of the respective column, and then, when the transistor is enabled there is a conducting path between the read and write bit lines. The conducting path means there is a connection between an input node and an output node of a currently addressed cell of the respective column. When the cells are suitably initialized, the conducting path allows for selected cells from the column to be used for logic operations. The logic operations may be on data already stored in the cell. As the cell has non-destructive readout the data may be retained and further logic operations are possible on the same data.

For example, if the output nodes of the currently addressed cells are initialized to 1, and the added transistor is set, then the selected cells may operate as logic cells.

Reference is now made to FIG. 8, which illustrates a method according to the present embodiments, of carrying out processing in memory logic operations on a memory array constructed with gain cell (GC) embedded dynamic random access memory (eDRAM). As above, cells of GC eDRAM are connected in columns between a respective write bit line and a read bit line 80. The method comprises selecting cells in one of the columns for a processing in memory logic operation, 82. The additional transistor referred to above is then set 84, so as to connect the respective read bit line to the respective write bit line of the same column. The result is a conducting path between inputs and outputs of the selected cells. The common output of the selected cells is set 86 to a value of 1, and a logic operation is carried out on the data stored in the selected cell.

As before, the data readout is non-destructive, so further logic operations may be carried out on the selected cells and the same data. Alternatively the logic result may be stored elsewhere and a further logic operation may be carried out on the stored result.

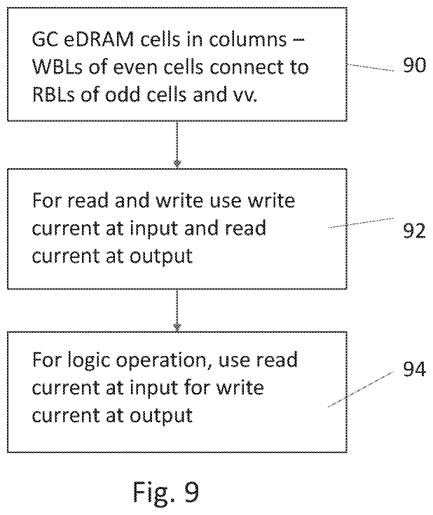

Reference is now made to FIG. 9, which illustrates a further embodiment according to the present invention of a method of carrying out logic operations in a gain cell (GC) embedded dynamic random access memory (eDRAM) device. As with FIG. 6 above, the device has bit cells arranged in rows and columns and the rows may be considered as alternate odd rows and even rows. For each column, write-bit-lines (WBLs) of bit cells in even rows are connected to read-bit-lines (RBLs) of bit cells in odd rows; and WBLs of bit cells in odd rows are connected to RBLs of bit cells in even rows 90. In normal use for memory read and write 92 the input obtains a write current to write into the storage and the output carries the read current from reading the stored data. The logic use for a given cell, 94, uses a read current of respective inputs as a write current for the respective output, and thus provides an output which depends on states at the respective inputs.

Multiple logic operations may be carried out across an array, where the array has numerous cells in numerous rows and columns, and the logic operations may use inputs in even rows and receive outputs in odd rows, or use inputs in odd rows and receive outputs in even rows.

### General

It is expected that during the life of a patent maturing from this application many relevant GC-eDRAM cells and arrays will be developed and the scope of the term GC-eDRAM is intended to include all such new technologies a priori.

The terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment and the present description is to be construed as if such embodiments are explicitly set forth herein. Conversely, various features of the invention, which are, for brevity, described in the context of a single embodiment, may also be provided separately or in any suitable subcombination or may be suitable as a modification for any other described embodiment of the invention and the present description is to be construed as if such separate embodiments, subcombinations and modified embodiments are explicitly set forth herein. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. An integrated circuit device comprising gain cell (GC) embedded dynamic random access memory (eDRAM) for memory storage, the GC eDRAM comprising:
an array of bit cells arranged in columns, each bit cell extending between a read bit line and a write bit line of a respective column;
an additional transistor for each column, connected between the respective read bit line and respective write bit line of the column, wherein the additional transistor, when enabled, provides a conducting path between the read bit line and the write bit line of the respective column, thereby to enable a logic operation within a currently addressed bit cell in the column.

2. The device of claim 1, configured to initialize an output node of the currently addressed bit cell to a value of 1 for said logic operation.

3. The device of claim 1, wherein two bit cells of said array are configured, with said additional transistor of their respective column, to operate as a NOT gate.

4. The device of claim 1, wherein three bit cells of said array are configured with said additional transistor of a respective column to operate as a NOR gate.

5. A method of manufacture of a device comprising a gain cell (GC) embedded dynamic random access memory (eDRAM)memory array for enabling processing-in-memory (PIM) operations, the method comprising:
providing a memory circuit in which GC eDRAM cells are arranged in columns between respective read bit lines and write bit lines;
adding a transistor for each column respectively, the added transistor connecting between the read bit line and the write bit line of the respective column, such that the transistor when enabled provides a conducting path between the read and write bit lines, thereby connecting between an input node and an output node of a currently addressed cell of the respective column.

6. The method of claim 5, comprising:
initializing the output node of a currently addressed cell with a value of 1;
enabling said added transistor; and
carrying out a logic operation on the data in the currently addressed cell.

7. A method of carrying out processing in memory logic operations on a memory array constructued with gain cell (GC) embedded dynamic random access memory (eDRAM) in which cells of GC eDRAM are connected in columns between a respective write bitiline and a read bit line, the method comprising:
selecting cells in one of said columns for a processing in memory logic operation:
in said column conditionally connecting the respective read bit line to the respective write bit line of the same column thereby providing a conducting path between inputs and outputs of the selected cells;
initializing the outputs of the selected cells to a value of 1;
carrying out a logic operation on the data stored in the selected cell.

8. The method of claim 7, comprising carrying out a further logic operation on the selected cell.

9. The method of claim 7, comprising storing a result of said logic operation in a further cell and carrying out a logic operation involving said further cell.

10. A device comprising gain cell (GC) embedded dynamic random access memory (eDRAM), the device comprising:
an array of GC eDRAM bit cells arranged in columns and rows, adjacent rows being designated odd rows and even rows respectively;
wherein for each column, connections are provided such that write-bit-lines (WBLs) of bit cells in respective even rows are connected to read-bit-lines (RBLs) of bit cells in respective odd rows; and WBLs of bit cells in respective odd rows are connected to RBLs of bit cells in respective even rows.

11. The device of claim 10, wherein said connections enable logic operations to be performed using read currents of bit cell inputs as write currents for respective bit cell outputs, thereby to provide outputs which are dependent on input states.

12. A method of carrying out logic operations in a gain cell (GC) embedded dynamic random access memory (eDRAM) device, the device having bit cells arranged in rows and columns and having odd rows and even rows, wherein for each column, write-bit-lines (WBLs) of bit cells in even rows are connected to read-bit-lines (RBLs) of bit cells in odd rows; and WBLs of bit cells in odd rows are connected to RBLs of bit cells in even rows, the method comprising for a given cell, using a read current of respective inputs as a write current for the respective output, thereby to provide an output which depends on states at said respective inputs.

13. The method of claim 12, comprising carrying out a plurality of logic operations across said array, using inputs in even rows and receiving outputs in odd rows, or using inputs in odd rows and receiving outputs in even rows.
